(19) United States
(12) Patent Application Publication
(10) Pub. No.: US 2014/0195191 A1
(43) Pub. Date: Jul. 10, 2014

(54) VOLTAGE TESTING DEVICE AND METHOD FOR MEMORY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAO HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/056,249

(22) Filed: Oct. 17, 2013

(30) Foreign Application Priority Data
Jan. 5, 2013 (CN) 2013100018797

(51) Int. Cl. G11C 29/50

(52) U.S. Cl. CPC G11C 29/50
USPC 702/119

(57) ABSTRACT

The disclosure provides a voltage testing device and a method. The voltage testing method includes following steps. The computer sets initial setting parameters for an oscillograph and a signal producer. The signal producer sends an initial pulse signal to an input terminal of a memory. The computer receives initial testing parameters of an output terminal of the memory and the initial voltage value of the input terminal sent by the oscillograph, and sends a current voltage offset and a current voltage undulating value to the control unit. The computer sends a current voltage value to the signal producer. The signal producer sends a current pulse signal to the input terminal. The oscillograph obtaining voltage values of the input and output terminals, produces two voltage waves, and sends the two voltage waves and the voltage values to the computer. The computer displays the two voltage waves and the voltage values.

### BACKGROUND

1. Technical Field

The present disclosure generally relates to a voltage testing device and method for a memory.

2. Description of Related Art

After a computer is manufactured, an overall test is required to check the quality. The memory test is one of the most important tests. A common method for testing the memory is to use a conventional device to test the memory and to record corresponding data manually, which is inefficient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a voltage testing device.

FIG. 2 is a flow chart of one embodiment of a voltage testing method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

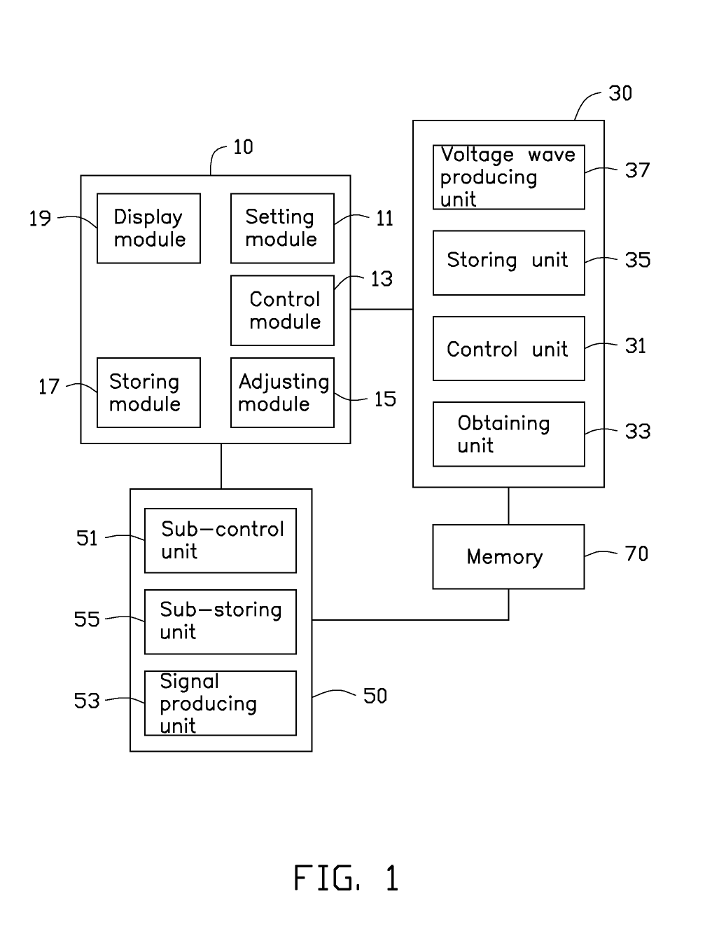

FIGS. 1 and 3 show a voltage testing device according to one embodiment. The voltage testing device includes a computer 10, an oscillograph 30 connected to the computer 10, and a signal producer 50. The oscillograph 30 includes a plurality of probes (not shown) for connecting to an output terminal of a memory 70 and the signal producer 50. The signal producer 50 is connected to the input terminal of the memory 70.

The computer 10 includes a setting module 11, a control module 13, an adjusting module 15, a storing module 17, and a display module 19.

The oscillograph 30 includes a control unit 31, an obtaining unit 33, a storing unit 35, and a voltage wave producing unit 37.

The signal producer 50 includes a sub-control unit 51, a signal producing unit 53, and a sub-storing unit 55.

The setting module 11 is used for setting initial setting parameters of the oscillograph 30, such as time reference, initial voltage offset, signal name, triggering reference, testing items, and initial voltage undulating value, for example, and storing the initial setting parameters to the storing module 17. The setting module 11 is used for setting initial setting parameters of the signal producer 50, such as pulse frequency, high level voltage, and low level voltage, and storing the initial setting parameters of the signal producer 50 to the storing module 17. The control module 13 is used for sending the initial setting parameters of the oscillograph 30 to the control unit 31 and sending the initial setting parameters of the signal producer 50 to the sub-control unit 51. The control unit 31 is used for storing the initial setting parameters of the oscillograph 30 to the storing unit 35. The sub-control unit 51 is used for storing the initial setting parameters of the signal producer 50 to the sub-storing unit 55.

The obtaining unit 33 is used for obtaining the initial voltage value of the input terminal of the memory 70 and initial testing parameters of the output terminal of the memory 70 when the signal producing unit 53 sends a pulse signal to the input terminal of the memory 70. The initial testing parameters includes a voltage maximize value and a voltage minimal value during a period of time. The control unit 31 is used for sending the initial testing parameters and the initial voltage value to the adjusting module 15. The adjusting module 15 is used for sending a current voltage offset and a current voltage undulating value to the control unit 31 of the oscillograph 30 according to the initial testing parameters, sending a current voltage value to the sub-control unit 51 of the signal producer 50 according to the initial voltage value, and storing the current voltage offset, the current voltage undulating value, and the current voltage value to the storing module 17. The control unit 31 is used for storing the current voltage offset and the current voltage undulating value in the storing unit 35. The sub-control unit 51 is used for storing the current voltage value in the sub-storing unit 55.

The obtaining unit 33 is further used for obtaining voltage values during a period of time of the input terminal and the output terminal after the storing unit 35 stores the current voltage offset and the current voltage undulating value, and sending the voltage values during the period of time to the voltage wave producing unit 37. The voltage wave producing unit 37 is used for producing two voltage waves according to the voltage values during the period of time and sending the two voltage waves and the voltage values during the period of time to control module 13 of the computer via the control unit 31. The control module 13 is further used for displaying the two voltage waves and the voltage values during the period of time on the display module 19.

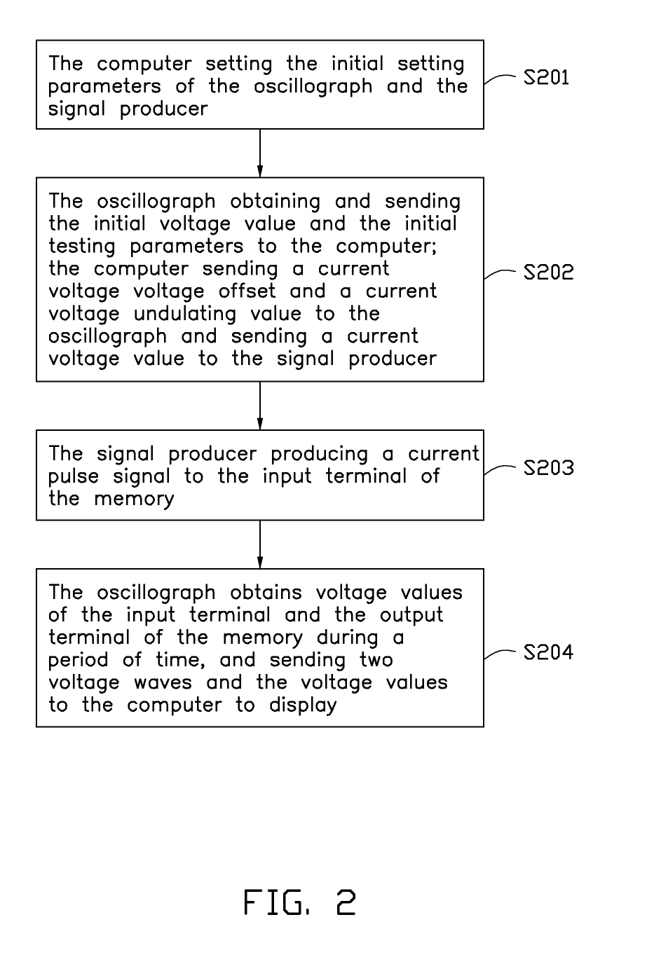

FIG. 2 shows that a voltage testing method for the memory 70, according to one embodiment, includes following steps.

S201, the setting module 11 sets the initial setting parameters of the oscillograph 30 and the signal producer 50 and stores the initial setting parameters to the storing module 17; the control module 13 sends the initial setting parameters of the oscillograph 30 to the control unit 31; the control module 13 sends the initial setting parameters of the signal producer 50 to the sub-control unit 51; the control unit 31 stores the initial setting parameters of the oscillograph 30 in the storing unit 35; and the sub-control unit 51 stores the initial setting parameters of the signal producer 50 in the sub-storing unit 55.

S202, the obtaining unit 33 obtains the initial voltage value of the input terminal of the memory 70 and initial testing parameters of the output terminal of the memory 70 when the signal producing unit 53 sends a pulse signal to the input terminal of the memory 70. The control unit 31 sends the initial testing parameters and the initial voltage value to the adjusting module 15; the adjusting module 15 sends a current voltage offset and a current voltage undulating value to the control unit 31 of the oscillograph 30 according to the initial testing parameters, sends a current voltage value to the sub-control unit 51 of the signal producer 50 according to the initial voltage value, and stores the current voltage offset, the current voltage undulating value, and the current voltage value to the storing module 17. The control unit 31 stores the current voltage offset and the current voltage undulating value in the storing unit 35. In addition, the sub-control unit 51 stores the current voltage value in the sub-storing unit 55,

S203, the signal producing unit 53 of the signal producer 50 produces a current pulse signal to the input terminal of the memory 70 according to the current voltage value.

S204, the obtaining unit 33 obtains voltage values of the input terminal and the output terminal of the memory 70 during a period of time, and sends the voltage values to the voltage wave producing unit 37; the voltage wave producing unit 37 produces two voltage waves according to the voltage values and sends the two voltage waves and the voltage values to the control module 13 via the control unit 31; and the control module 13 displays the two voltage waves and the voltage values on the display module 19.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A voltage testing device comprising:
a signal producer, the signal producer comprises a sub-control unit and a signal producing unit;
an oscillograph, the oscillograph comprises a control unit, an obtaining unit, a storing unit, and a voltage wave producing unit; and the oscillograph is configured to an input terminal and an output terminal of a memory;
a computer, the computer comprises a control module, an adjusting module, and a display module; the control module is configured to send first initial setting parameters to the control unit and send second initial setting parameters to the sub-control unit;
wherein the control unit is configured to store the first initial setting parameters in the storing unit; the obtaining unit is configured to obtain an initial voltage value of the input terminal and initial testing parameters of the output terminal when the signal producer sends an initial pulse signal to the input terminal; the control unit is further configured to send the initial testing parameters and the initial voltage value to the adjusting module; the adjusting module is configured to send a current voltage offset and a current voltage undulating value to the control unit, according to the initial testing parameters, and to send a current voltage value to the sub-control unit, according to the initial voltage value; the obtaining unit is further configured to obtain voltage values of the input terminal and the output terminal during a period time after the storing unit stores the current voltage offset and the current voltage undulating value and the signal producing unit sends a current pulse signal to the input terminal according to the current voltage value; the voltage wave producing unit is configured to produce two voltage waves corresponding to the input terminal and the output terminal, according to the voltage values, and to send the two voltage waves and the voltage values to the control module; and the control module is further configured to display the voltage values and the two voltage waves on the display module.

2. The voltage testing device of claim 1, wherein the computer further comprises a storing module, and the storing module is configured to store the current voltage offset, the current voltage undulating value, and the current voltage value.

3. The voltage testing device of claim 1, wherein the first initial setting parameters comprises initial voltage offset and initial voltage undulating value.

4. The voltage testing device of claim 1, wherein the second initial setting parameters comprises pulse frequency, high level voltage, and low level voltage.

5. The voltage testing device of claim 1, wherein the initial testing parameters comprise a voltage maximize value and a minimal value during another period of time.

6. A voltage testing method, applied in a voltage testing device, comprising:
setting initial setting parameters for an oscillograph and a signal producer by a computer;
sending an initial pulse signal by the signal producer to an input terminal of a memory;
receiving initial testing parameters of an output terminal of the memory and the initial voltage value of the input terminal sent by the oscillograph by the computer;
sending a current voltage offset and a current voltage undulating value by the computer to the oscillograph according to the initial testing parameters; and sending a current voltage value by the computer to the signal producer according the initial voltage value;
sending a current pulse signal by the signal producer to the input terminal according to the current voltage value;
obtaining voltage values of the input terminal and the output terminal during a period of time by the oscillograph, producing two voltage waves corresponding to the input terminal and the output terminal according to the voltage values by the oscillograph, and sending the two voltage waves and the voltage values to the computer by the oscillograph; and
displaying, by the computer, the two voltage waves and the voltage values.

7. The voltage testing method of claim 6, wherein the current voltage offset, the current voltage undulating value, and the current voltage value are stored in the computer.

8. The voltage testing method of claim 6, wherein the initial setting parameters comprises initial voltage offset and initial voltage undulating value.

9. The voltage testing method of claim 6, wherein the initial setting parameters of the signal producer comprises pulse frequency, high level voltage, and low level voltage.

10. The voltage testing method of claim 6, wherein the initial testing parameters comprise a voltage maximize value and a minimal value during another period of time.
